(19) United States
(12) Patent Application Publication
(10) Pub. No.: US 2011/0008525 A1
(43) Pub. Date: Jan. 13, 2011

(54) CONDENSATION AND CURING OF MATERIALS WITHIN A COATING SYSTEM

(75) Inventors: George Theodore Dalakos, Niskayuna, NY (US); Christian Maria Anton Heller, Albany, NY (US); Ahmet Gun Erlat, Clifton Park, NY (US)

Correspondence Address: GE TRADING & LICENSING, 1 RESEARCH CIRCLE, ATTN: BRANDON, K1 - 2A62A, NISKAYUNA, NY, 12309, US

(73) Assignee: General Electric Company, Schenectady, NY (US)

(21) Appl. No.: 12/501,308

(22) Filed: Jul. 10, 2009

(51) Int. Cl. B05D 5/12; B05D 3/04; C23C 16/00; B05D 3/06

(52) U.S. Cl. 427/2.11; 427/488; 118/722; 427/248.1; 427/508; 427/66; 427/74; 427/96.8; 427/58; 427/69

(57) ABSTRACT

Present embodiments are directed to a system and method for condensing and curing organic materials within a deposition chamber. Present embodiments may include condensing an organic component from a gas phase into a liquid phase on a target surface within the deposition chamber, wherein the gas phase of the organic component might be mixed with an inert gas. Further, present embodiments may include solidifying the liquid phase of the organic component into a solid phase within the deposition chamber using an inert plasma formed from the inert gas.

### BACKGROUND OF THE INVENTION

The present disclosure relates generally to coating a substrate or component. More particularly, present embodiments are directed to a process for delivering, condensing and curing materials within the confines of a plasma-enhanced chemical vapor deposition (PECVD) system.

Plasma-enhanced chemical vapor deposition (PECVD) may be described as a process for depositing thin films from a gas state (vapor) to a solid state on a surface. For example, plasma deposition may be employed in semiconductor manufacturing to deposit films onto a wafer that includes temperature-sensitive structures (e.g., metal layers). Plasma deposition may also be employed on temperature-sensitive structures such as organic substrates, organic LEDs and so forth. The PECVD process may generally include various steps. For example, the PECVD process may include generating a glow discharge (plasma) by using electrical energy to transfer energy into a gas mixture. Precursors of sufficient volatility may be introduced as gases into the plasma and reactive components (radicals) may be formed. These reactive components may then interact with a substrate such that they chemically bond or cross link (cure) on the substrate. Because the formation of the reactive components in the gas phase occurs by collision within the gas phase, the substrate may be kept at a low temperature, and, thus, film formation using PECVD can be achieved on substrates at lower temperatures than can typically be done by traditional, thermal chemical vapor deposition procedures.

PECVD processes may be utilized to provide coatings that include both organic and inorganic components. For example, in ultra high barrier (UHB) coating designs for organic light emitting devices (OLEDs) and other optoelectronic devices that degrade with moisture and oxygen, it is often necessary to have both organic and inorganic materials within the same coating. Multilayered and graded UHBs are the most common examples of such structures. With regard to multilayered UHBs, in general, organic layers and inorganic layers are typically prepared by subsequent processes that require movement of an object being coated between two or more specialized deposition systems. In some cases, plasma polymerized organic materials, such as in the case of graded ultra-high barriers, may be prepared by the same deposition equipment as inorganic materials. This is typically performed using a PECVD process. Unfortunately, while existing PECVD processes may facilitate depositing both organic and inorganic films, it is now recognized that plasma polymerized films cannot be spread like a liquid in the existing PECVD processes and, thus, the benefits of such spreading (e.g., smoothing out asperities, filling pores, and filling cracks) are not available in such processes. With regard to graded barriers, further information may be found in U.S. Pat. No. 7,015,640.

### BRIEF DESCRIPTION OF THE DRAWINGS

Advantages of the present embodiment may become apparent upon reading the following detailed description and upon reference to the drawings in which:

FIG. 1 illustrates process steps, and the associated system components and substrate as they go through a procedure in accordance with present embodiments;

FIG. 2 is a system diagram that illustrates three precursor delivery mechanisms in accordance with present embodiments;

FIG. 3 is a cross-sectional view of the surface of a substrate after a coating has been condensed on the substrate in accordance with present embodiments;

FIG. 4 illustrates menisci formation on a substrate with various structural features over time and with varying condensation thicknesses in accordance with present embodiments;

FIG. 5 illustrates a series of conceptual cross-sectional views of a system, substrate, and depositional components as a procedure progresses in accordance with present embodiments; and

FIG. 6 illustrates a barrier with an organic coating formed over a surface feature of a substrate in accordance with present embodiments.

### DETAILED DESCRIPTION OF SPECIFIC EMBODIMENTS

One or more specific embodiments of the present invention are described below. In an effort to provide a concise description of these embodiments, not all features of an actual implementation are described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

Traditional procedures for forming a smoothing and a barrier coating include the use of two separate thin film fabrication techniques to form the smoothing and barrier layers. It is now recognized that most cases involving a separate smoothing layer approach can be slow and costly. Accordingly, it is now recognized that it is desirable to achieve a process that maintains or improves barrier performance over severe surface topology while potentially lowering tact time and increasing throughput. Further, it is now recognized that it may be desirable to enable all processing in a single chamber instead of separate wet coating or flash evaporation processes for smoothing layers. It should be noted that the term “chamber” or “deposition chamber” is used herein to generally refer to an enclosure that, among other things, is capable of fully containing a gas that can be converted into a plasma within the enclosure.

Present embodiments are directed to a PECVD system and process for condensing and curing smoothing layer and barrier coating materials in a single chamber. Specifically, present embodiments are directed to forming a smoothing layer and a barrier coating in the same coating system, such as a PECVD reactor. In some embodiments, a smoothing layer may be applied to a substrate surface and a barrier coating may be disposed on the smoothing layer. Additionally, in some embodiments smoothing layer material may be disposed on the barrier coating as a top layer or a thick layer. Such a top layer may provide impact and/or abrasion resistance. Multiple additional layers may also be disposed over the smoothing layer or the barrier coating in accordance with present embodiments. Further, present embodiments may cure polymer layers using the same energy source (e.g., plasma source) that is used for barrier deposition. Thus, present embodiments facilitate efficient preparation of both a robust smoothing layer and the barrier coating on a substrate or device part, wherein the robust smoothing layer includes a volatile precursor. Indeed, providing the smoothing layer and subsequent PECVD deposition in the same system may save equipment costs and allow the substrate to remain in the same chamber for both procedures, which can potentially reduce the tact time and the potential of particle contamination from handling (e.g., moving the substrate between applying the smoothing layer and a subsequent barrier coating and/or a subsequent smoothing layer).

It should be noted that, in accordance with present embodiments, the robust smoothing layer may include a volatile precursor delivered into the system, selectively condensed onto surfaces, and cured using plasma and/or other sources. When used in conjunction with a thin film barrier structure, the robust smoothing layer may maintain or improve barrier efficacy in the presence of surface structures and/or contamination (e.g., particles) that would typically limit the performance of the thin film barrier. Additionally, present embodiments may provide physical flexibility, fine control over material being utilized, and three dimensional curing via the use of plasma curing.

As described in detail below, present embodiments include a process within the confines of a PECVD system that will facilitate selective condensation of organic material and subsequent plasma curing of the condensed organic material to form solid material. Such material may be utilized for barrier and hardcoat technology utilized for OLED and solar-photovoltaic applications to name a few. Indeed, present embodiments may be used in producing an organic and/or inorganic material-based barrier coating for a wide variety of organic electronics and optoelectronic applications. The robust coating combined with the barrier coating may be applied to a number of devices requiring encapsulation (e.g., OLEDs and solar cells). Present embodiments may include depositing a barrier on a smoothing layer and depositing another smoothing layer on the barrier and so forth. For example, present embodiments may be used for applications relating to hardened polymer top coats, providing abrasion resistance and impact resistance to the same previously mentioned end applications.

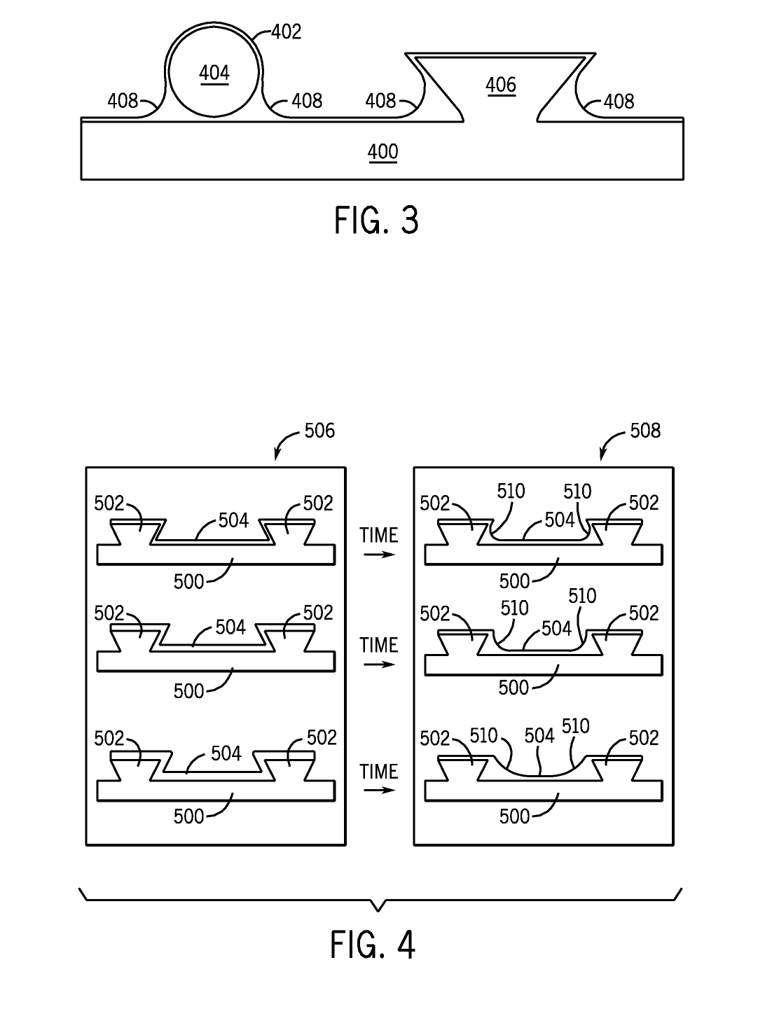

In general, deposition of smoothing layer material in accordance with present embodiments may result in a robust smoothing layer or thin film coating that functions as a smoothing layer, and an abrasion and/or impact-resistant protective coating. When applied before a thin-film barrier, the smoothing property of the film may facilitate use of thinner PECVD coating and thus may reduce tact time and film stress. Given that cross-linked films typically are under tensile stress and PECVD coatings are often under compressive stress, the combination may balance out the combined stresses, which may facilitate maintaining a thin, flat film, and avoid delamination issues. Due to the viscous flow of the condensed liquid, a resulting material may enable barriers or protective coatings to be applied to thoroughly coat difficult-to-coat features, such as passive-matrix lines and particles on a substrate, as discussed in further detail below with regard to features 404 and 406 of FIG. 3. Further, present embodiments may facilitate rapid application of a smoothing layer (e.g., application in seconds instead of minutes).

In accordance with present embodiments, feedstock may be introduced in a gas phase and transported to the vicinity of a component (e.g., a substrate or part to be coated). Once in the vicinity of the component, the feedstock gas may be condensed into a liquid on the surface of the component. Subsequent curing or cross linking of the condensed liquid into a solid material may be accomplished by employing an inert plasma source. Indeed, by using the inert plasma source, viscous flow mass transport may be realized at very low temperatures which may facilitate selectively coating areas that cannot be accomplished in such a fashion through traditional vapor phase mass transport mechanisms. The resulting material can better smooth out or fill in pores and/or cracks on the component (e.g., substrate) or underlying layers. Specifically, by utilizing a PECVD-like process that offers liquid viscous mass transport and subsequent curing within the PECVD process, present embodiments may enable difficult surface topography to be continuously coated without the need for a separate organic process. It should be noted that coatings in accordance with present embodiments may or may not include continuous films. Further, it should be noted that applications of present embodiments may include barrier or encapsulation coatings and abrasion and/or impact-resistant over-layers. Indeed, the film may be suitable for a relatively thick top coat for mechanical protection.

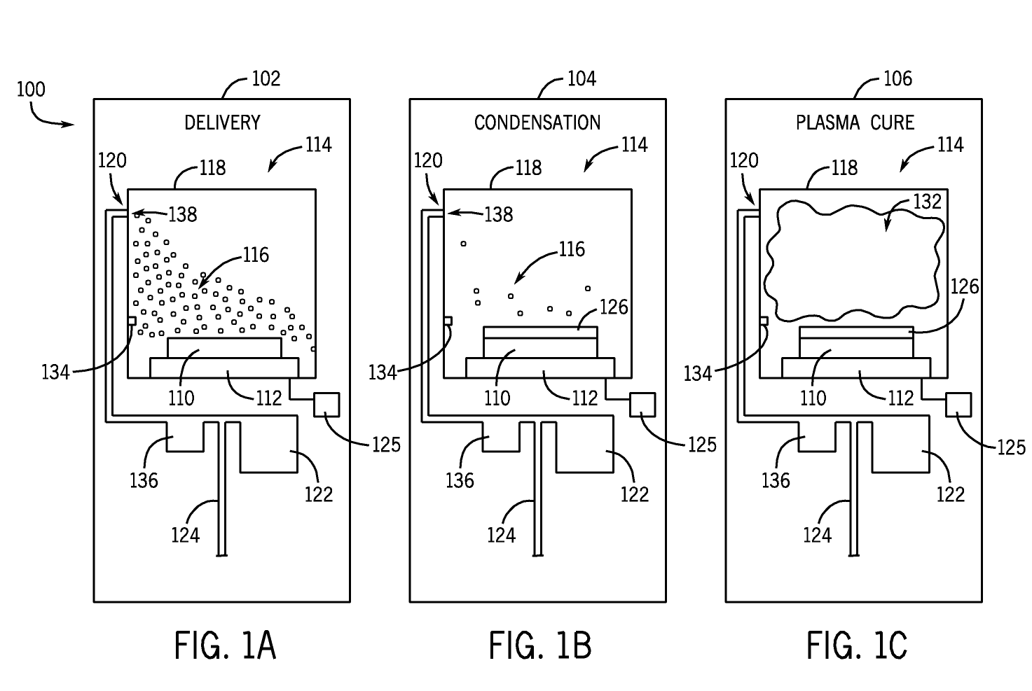

FIG. 1 illustrates process steps, and the associated system components and substrate as they go through a procedure in accordance with present embodiments. The process is generally indicated by reference numeral 100. The process 100 includes three main steps, which include a delivery step 102, a condensation step 104, and a plasma cure step 106. Each step is represented by a conceptual cross-sectional view of a substrate 110 disposed on an electrode 112 in a reactor system 114 in accordance with present embodiments. It should be noted that some steps include multiple procedures. Further, as would be understood by one of ordinary skill in the art, additional steps could be illustrated and/or performed.

In the delivery step 102, precursor vapor 116 may be introduced into a process chamber 118 through an inlet 120 to pass over the substrate 110 and the electrode 112. An organic precursor source container 122 that supplies the inlet 120 may be heated to a temperature corresponding to a target vapor pressure. Indeed, in some embodiments, a sufficient vapor pressure may be created to force flow through the inlet 120. To prevent premature thermal cross-linking of the precursor in the source container, heating may be done in a heater between a flow control feature of the inlet 120 and the source container and/or a gas (e.g., oxygen) may be used to inhibit premature cross-linking. Further, delivery lines of the inlet 120 may be heated to avoid condensation in the lines. In addition, the (cold) precursor source container 122 may be put under elevated inert-gas pressure to facilitate precursor delivery whenever the vapor pressure of the (cold) precursor is not sufficient. As discussed below, various features may be utilized to control the amount of flow through the inlet.

At a tee or intersection of the inlet 120, precursor may flow into a metered inert gas stream 124 or the inert gas may be passed through a heated precursor reservoir resulting in a well-mixed gas. Sufficiently long distances in the inlet 120 may be used to assure sufficient mixing. The gas mixture may then be expanded into a lower pressure reaction zone (e.g., the process chamber 118) within the reactor system 114.

The inlet 120 may include and/or utilize any of various features to introduce the precursor vapor 116 into the chamber 118. For example, in some embodiments, the inlet 120 may include a mass flow controller (MFC) that operates based on a vapor pressure of precursor within a heated reservoir being sufficient to drive the MFC, which may also be heated. In some embodiments, the inlet 120 may include a metering valve that controls vapor flow based on pressure drop, and/or a bubbler that uses inert gas to entrain precursor up to saturation. Further, in some embodiments, the vapor inlet may include a throttle for throttling liquid into the process chamber 118, which may be kept at a low pressure relative to the source of the liquid. Similarly, the inlet 120 may include a high-pressure injector, such as a fuel-injector, that sprays the liquid into the chamber 118, which may be heated. The use of such an injector may limit the amount of time in which the precursor can partially cross-link due to the high temperature.

During the delivery step 102, inert gas may be flowed with the precursor into the reactor system 112 and over target surfaces (e.g., the exposed surface of the substrate 110) to form liquid phase deposits on the target surfaces via condensation during the condensation step 104. The liquid phase may be a stable liquid phase, which may be defined as a liquid phase that maintains its phase for at least one second. In other words, a stable liquid phase is a liquid phase that does not solidify or evaporate for more than one second. The delivery step 102 and the condensation step 104 may overlap in that the precursor may either condense at under-saturated conditions by capillary condensation or normal condensation at saturated/super-saturated conditions. This may be primarily controlled by a condensation control system 125 of the chamber 118 that controls the substrate temperature and/or precursor partial pressure. The temperature of the substrate 110 may be controlled by adjusting the temperature of the electrode 112 to a desired temperature for condensing the precursor vapor 116. It should be noted that control of certain flows, temperatures, and pressures may be handled by a programmed controller, such as a computer programmed with a control algorithm, that utilizes set points and sensors to control certain aspects of present embodiments.

To avoid or limit condensation on surfaces other than the target surface (e.g., the target surface of the substrate 110), all non-target surfaces may be sufficiently heated to prevent condensation, especially surfaces where substantial pressure drops are likely to occur (e.g., tees, elbows, showerhead holes). Another approach to limiting undesired condensation may be to limit the precursor vapor pressure by either inserting a baffle with a temperature below (e.g., 5 to 10° C. below) the lowest temperature of a surface where condensation should not occur, or by measuring the precursor partial pressure and using this value for precise metering. Various methods and features may be utilized to promote condensation on the target surfaces while avoiding condensation on other surfaces, as will be discussed in further detail below.

During the condensation step 104, the organic precursor gas and inert gas mixture (e.g., the precursor vapor 116) may flow over the substrate 110, which may be cooled to establish the target deposit area. The cooled temperature of the substrate 110 may be maintained by a refrigerant or some other method. The substrate 110 may also be unheated if the temperature is sufficient to allow adequate condensation. In the condensation step 104, the precursor vapor 116 may condense on the cooled target area of the substrate 110 to form a condensate layer 126, which may include a liquid phase of a desired extent or thickness. The condensation step 104 may include blocking flow of the precursor vapor 116 from the inlet 120 to facilitate condensing the precursor vapor 116 to the condensed liquid layer 126. For example, this may include closing a valve from a reservoir that supplies the precursor vapor at a time set for condensation. The time allowed for condensation may be determined based on condensation rate or menisci to reach steady state. In some embodiments, viscous flow of the inert gas may be allowed to progress briefly (e.g., several seconds) while the precursor gas has been stopped, which may allow time for excess precursor vapor to be vented.

Regarding the plasma cure step 106, plasmas may emit vacuum ultra-violet (VUV), ultra-violet (UV), and visible (VIS) light, which may cure a condensed precursor liquid into a solid material. In addition, a plasma source may contain electrons and ions that can further assist in curing the precursor liquid. Unique material properties may be realized by plasma curing versus conventional radiation curing. The plasma cure step 106 may include initiating a plasma treatment in accordance with present embodiments. Specifically, the plasma cure step 106 may include introduction of inert plasma 132 into the chamber 118, thus exposing the target surface of the substrate 110. The plasma 132 may be formed by igniting the inert gas discharge. The amount of inert plasma 132 may be controlled such that the target surfaces are exposed at a desired dose as determined by the time and power calculated to form cross-linked material, final film properties, and so forth.

In addition to or replacement of the inert plasma 132, present embodiments may include a UV source 134 (e.g., a grid lamp filled with Xe or Hg vapor) to cure the condensed liquid layer 126. The UV source 134 may accelerate or replace the plasma-induced polymerization of the condensed liquid. The UV source 134 may be mounted to a showerhead and energized with its own electrodes or by the RF field of the PECVD system. In some embodiments, the UV source may be positioned outside PECVD electrodes for relatively large ratios of electrode-gap to electrode-width, and the UV source may be projected onto the substrate 110 directly. An electrode finish with high UV reflectivity may be selected and a UV ring light may be placed around the electrodes. Further, the substrate 110 may be shuttled out of the PECVD position to a UV-cure position. Once the condensed liquid layer 126 is cured, the process 100 may be repeated to achieve desired results, such as a final film thickness (e.g., a certain thickness of a homogeneous organic layer), building of consecutive layers or material, and so forth.

As indicated above, various methods and features may be utilized to promote condensation on the target surfaces while avoiding condensation on other surfaces. Indeed limiting precursor condensation on all but the substrate 110 may avoid significant maintenance issues that are typical with traditional flash evaporators. Present embodiments may even substantially eliminate undesired condensation on the bottom electrode, which is relatively cold, using disposable or cleanable masks.

With regard to limiting undesirable condensation, in one embodiment, the delivery step 102 may include heating the precursor inside the vapor inlet 120 to avoid condensation on the vapor inlet 120. For example, the vapor inlet 120 may include a showerhead, and, to avoid precursor condensation on the shower head, which could potentially deviate the process (e.g., block the showerhead holes and cause spitting), the surface temperature of the showerhead (and other equipment) and the partial pressures of the precursor may be controlled in accordance with present embodiments. The temperature may be controlled based on measurements obtained via thermocouples placed at certain points on the equipment, and the precursor partial pressure may be controlled based on measurements obtained via pressure gauges. However, standard pressure gauges may not be sufficiently precise for pressure measurements in accordance with present embodiments, and might degrade due to contamination by the precursor.

In some embodiments, vapor pressure control may be facilitated by using a trap. For example, as illustrated in FIG. 1, the vapor inlet 120 may include a trap 136 that is positioned prior to an entry point 138 (e.g., a showerhead). The trap 136 may be kept at a lower temperature than the entry point 138 and other surfaces in the chamber 118 (e.g., 5° C. below the coldest non-condensing surface), which may limit the precursor vapor pressure by removing excess via condensation. In some embodiments, the precursor may be a precisely metered in response to its measured partial pressure, or the precursor and carrier gas may be precisely metered together with control of temperature and total pressure. Further, in some embodiments, vapor pressure may be controlled by bubbling a carrier gas through a precursor reservoir that is heated to a precise target temperature to saturate the gas.

One method of controlling condensation with the controller 125 may be based on measurements of vapor pressure using a known molecular extinction coefficient (ε) for the vapor at one of its ultra-violet (UV) or infra-red (IR) absorption peaks, which are typically separate from those of potentially used gases (e.g., N₂, Ar, O₂). With regard to the light source for the UV light, a Mercury or Deuterium lamp may be used. With regard to the light source for the IR light, a Halogen Lamp may be used. For detection of the light, a band-pass filter plus detector and/or a UV or IR spectrometer may be used. To correct for intensity fluctuations, a second signal may be measured that is independent of the precursor (e.g. a second IR wavelength where there is no precursor absorption, or a reference beam). To increase the signal-to-noise ratio or to allow measurement when a plasma is lit, the light source can be modulated for use with a lock-in amplifier.

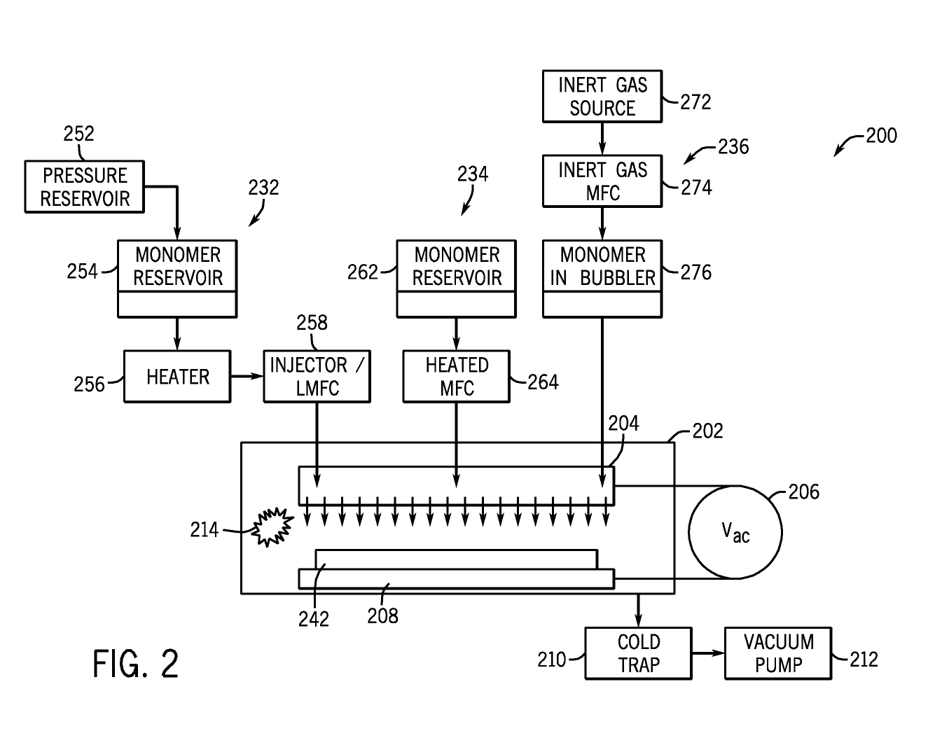

FIG. 2 is a system diagram that illustrates three precursor delivery mechanisms in accordance with present embodiments. The system is generally indicated by reference numeral 200. Specifically, the system 200 includes a hot-wall vacuum chamber 202, a showerhead 204, a PECVD power supply 206, a cooled bottom electrode 208, a cold trap 210, a vacuum pump 212, and a UV light 214. The system 200 also includes an injector system 232, a mass flow controller (MFC) system 234, and a bubbler system 236. Disposed within the system 200 is a sample 242 (e.g., a substrate). The system may include separate cooling and heating systems for the chamber 202, the showerhead 204, and the bottom electrode 208. Further, the system may include additional chillers and heaters for vapor inlet systems and precursor lines.

It should be noted that while the system 200 is illustrated as including three vapor inlet systems (i.e., the injector system 232, the MFC system 234, and the bubbler system 236), this is for illustrative purposes and embodiments may include one of the three. In other words, present embodiments may not include all three of the illustrated inlet systems. Indeed, present embodiments may include a vapor inlet or delivery system that is not illustrated. In accordance with present embodiments the inlet system may be capable of delivering material onto a target surface directly or indirectly regardless of line of sight. In other words, regardless of whether the inlet system would be visible from the target surface or aligned with the target surface, the inlet system may be capable of depositing material directly or indirectly onto the target surface.

The injector system 232 includes a pressure reservoir 252, a precursor reservoir 254, a heater 256, and an injector 258. The pressure reservoir 252 may use an inert gas to pressurize the precursor reservoir in 254. The heater 256 may maintain an appropriate temperature to reduce the potential for partial cross-link. The injector 258, such as a high-pressure fuel-injector, may operate to inject the precursor into the chamber 202 for condensation on the sample 242. In the illustrated embodiment, the injector 258 supplies the precursor to the chamber 202 via the showerhead 204.

The MFC system 234 includes a precursor reservoir 262 and a heated MFC 264. The precursor reservoir 262 may be heated such that the vapor pressure is sufficient to drive the heated MFC 264. The MFC 264 may monitor and control the amount of precursor supplied based on a desired amount for condensation on the sample 242. In the illustrated embodiment, the MFC 264 supplies the precursor to the chamber 202 via the showerhead 204.

The bubbler system 236 includes an inert gas source 272, an inert gas MFC 274, and a precursor bubbler 276. The inert gas supplied by the inert gas source 272 may be flowed into the precursor bubbler 276 via the inert gas MFC 274 and controlled by the inert gas MFC 274 such that a proper amount of inert gas is used to achieve a certain amount of vapor. For example, the precursor bubbler 276 may receive sufficient gas to entrain the precursor in the gas to a saturation condition for introduction into the chamber 202. In the illustrated embodiment, the bubbler 276 supplies the precursor to the chamber 202 via the showerhead 204.

Various precursors may be utilized in accordance with present embodiments. Desirable precursor candidates may include typical UV-curable precursors with a suitable vapor pressure. Potential precursors may also include certain molecules that are not easily UV-curable and depend on radical formation due to the plasma-induced electron and ion bombardment.

Various properties may be considered when selecting a precursor for use in accordance with present embodiments. For example, in some precursor families (e.g., mono-acrylates), the vapor pressure drops with increasing molecular weight, and, thus, can be too high for small derivatives and too low for large derivatives. Also, UV-induced shrinkage may vary with the ratio of the number of reactive sites to the size of the precursor. Thus, the tensile stress may be large for small triacrylates and small for large mono-acrylates, which may balance the compressive stress of a subsequently formed thin film. In addition, properties such as wetting, surface tension, and viscosity of the precursor liquid, and adhesion, crystallinity, hardness and other optical and mechanical properties of the cured film may vary. For example, certain properties may vary with linear or branched alkane groups. As another example, certain properties may vary with polar (OH), non-polar (F), or aromatic groups. Other conditions may cause variations as well. For example, plasma curing conditions may relate to an extent of wrinkling based on mechanisms known in the art.

Radiation-curable alkenes and alkynes may be used as precursor material in accordance with present embodiments. For example, such alkenes and alkynes may be represented by the formulas (R¹)(R²)—C═C—(R¹)(R²) and R¹—C≡C—R² wherein R¹ H, aliphatic, alicyclic, mixed aliphatic-alicyclic, aromatic, CN, halogen, COOR, O₂CR, silyl, stannyl, alkene, alkene-substituted alkane, alkene-functional aromatic, —COR, wherein R¹ and R² may be the same or different, and R may equal either an aliphatic or aromatic group substituted with R¹ such that the total number of carbon atoms ranges from about 3 to about 15. Specific examples include styrene, divinyl benzene, ethylene glycol diacrylate, propylene glycol diacrylate, butanediol diacrylate, neopenytlglycol, diacrylate, trimethylolpropane triacrylate, hexanediol diacrylate, hexanediol dimethacrylate, acrylonitrile, butyl acrylate, butyl methacrylate, dimethyl maleate, dimethyl fumarate, vinyltrimethoxysilane, methylvinylketone, vinyl bromide, ethyl propiolate, butadiene, and the like.

FIG. 3 is a cross-sectional view of the surface of a substrate or device 400 after a coating 402 has been condensed on the substrate 400 in accordance with present embodiments. The coating 402 may form over all surface structures, pores, and particles. For example, at superheated or undersaturated conditions, the liquid coating 402 may form steady state menisci across all surface features to the extent dictated by liquid, gas, and system properties. As illustrated in FIG. 3, the coating 402 may cover particles, such as the particle 404, and/or structures, such as the passive-matrix cathode partition line 406, on the surface of the substrate 400. The liquid film 402 has properties such that it limits or essentially minimizes its surface area due to its specific surface tension. Thus, even a very-thin continuous film 402 or local menisci 408 may smooth out cavities. This selective condensation may also stabilize particles (e.g., particle 404), which when moved after applying a barrier would typically locally destroy the barrier.

FIG. 4 illustrates menisci formation on a substrate 500 with various structural features 502 over time and with varying condensation thicknesses in accordance with present embodiments. Specifically, FIG. 4 illustrates a general shape of initial condensation of material 504 on the substrate 500 with varying thicknesses in block 506, and the relaxed film shape that the condensation material 504 takes over time in block 508. The relaxed film shape includes menisci 510. As illustrated by FIG. 4, assuming good wetting, thin films, low viscosity, and enough time, the menisci may be generally defined by circles in all concave regions.

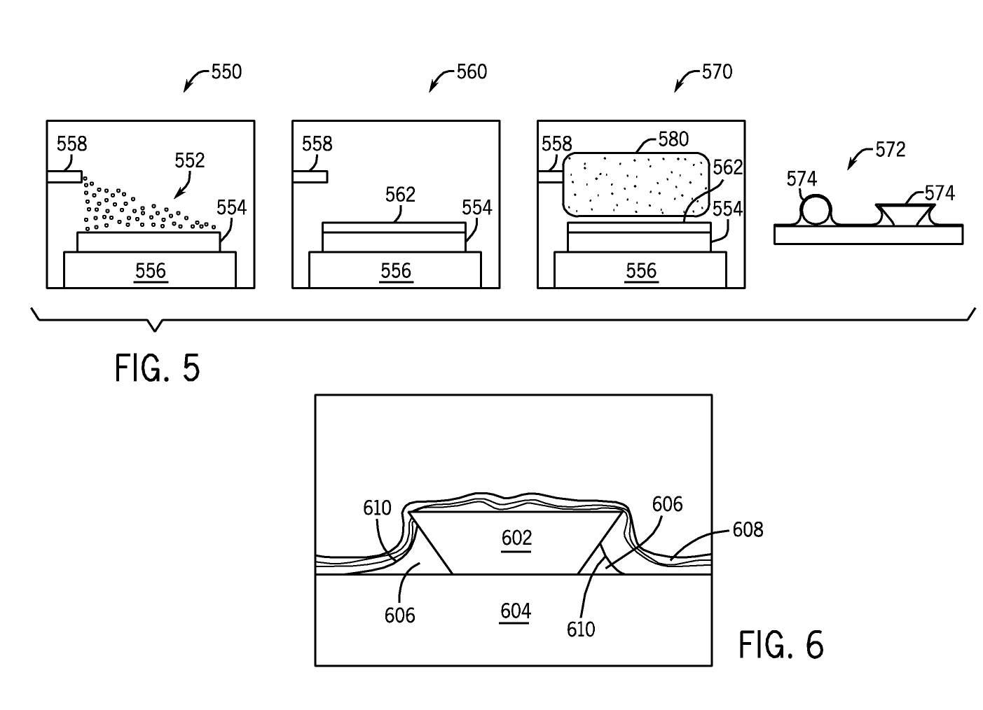

FIG. 5 illustrates a process in accordance with present embodiments. Specifically, FIG. 5 includes a set of cross-sectional views that generally represent different stages in the process of depositing a robust smoothing layer onto a substrate in accordance with present embodiments. A first step 550 represents depositing a precursor vapor 552 onto a substrate 554 positioned on an electrode 556 within a deposition chamber via a precursor inlet 558. In the first step 550 there are numerous procedural settings and adjustable variables that may vary in accordance with present embodiments. For example, the first step 550 may include setting a process chamber temperature, which may be achieved by adjusting an electrode temperature to a desired level. Also, the first step 550 may include setting a precursor reservoir temperature and a precursor line temperature. Multiple settings may be utilized if multiple zone heating is used. As a specific example of the settings for the first step 550 when two zones are used, the electrode temperature may be set to approximately 15° C., a reservoir/outside line temperature may be set to approximately 95° C., and an inside line (tube) temperature may be set to approximately 110° C.

A second step 560 illustrated in FIG. 5 represents condensation of the precursor 552 onto the substrate 554 as a precursor layer 562. Several variables that impact the second step 560 may be adjusted in accordance with present embodiments. Specifically, for example, a type of carrier gas, a flow rate of the carrier gas, system pressure, and a condensation time. As a specific example of the settings for the second step 560, nitrogen may be used as the carrier gas at a flow rate of 50 SCCM, at a system pressure of 500 mTorr, and with a condensation time of 10 seconds.

A third step 570 illustrated in FIG. 5 represents curing of the precursor layer 562 and the cross-section 572 represents a magnified view of the layer 562 formed over various surface features 574 of the substrate 554. Specifically, in the illustrated embodiment, a plasma 580 is introduced into the chamber to enable three dimensional plasma curing of the precursor layer 562. As with the previous steps, there are numerous variables that may be adjusted during the third step 570. Specifically, for example, a type of plasma cure gas, a flow rate of the plasma cure gas, a system pressure, a plasma cure time, and a plasma RF power. As a specific example of the settings for the third step 570, nitrogen may be used as the plasma cure gas, at a flow rate of 300 SCCM, at a system pressure of 2000 mTorr, a plasma cure time of 1 minute, and a plasma RF power of 230 W. Additionally, a PECVD UHB preparation step may be performed, wherein different PECVD electrode temperature settings, heating rates, and purging times may be utilized. In an exemplary embodiment, a dedicated reactor may be utilized for the robust layer independent of a UHB coating reactor.

FIG. 6 illustrates a barrier with an organic coating formed over a surface feature of a substrate in accordance with present embodiments. Specifically, FIG. 6 includes a passive-matrix cathode partition line 602 on a substrate 604 that are coated with an organic coating 606 and a barrier 608. Such a coating may be achieved through a process such as that illustrated in FIG. 5 in a single coating system (e.g., within a single PECVD system) in accordance with present embodiments. It should be noted that the organic coating 606 forms menisci 610 in the corners formed by the intersection of the passive-matrix cathode partition line 602 and the substrate 604.

While only certain features of the invention have been illustrated and described herein, many modifications and changes will occur to those skilled in the art. It is, therefore, to be understood that the appended claims are intended to cover all such modifications and changes as fall within the true spirit of the invention.

What is claimed is:

1. A method for delivering, condensing and curing materials within a deposition chamber, comprising:
condensing material from a gas phase into a liquid phase on a target surface within the deposition chamber; and
solidifying the liquid phase of the material into a solid phase within the deposition chamber using a plasma.

2. The method of claim 1, wherein the material comprises an organic material.

3. The method of claim 1, comprising delivering the material into the deposition chamber in the gas phase along with an inert gas.

4. The method of claim 3, comprising forming the plasma from the inert gas.

5. The method of claim 1, wherein the deposition chamber comprises a plasma enhanced chemical vapor deposition chamber.

6. The method of claim 1, wherein solidifying the liquid phase comprises facilitating solidification of the liquid phase of the material into the solid phase with a thermal curing feature, or an ultra-violet light source, or an ultraviolet and visible light source disposed within the deposition chamber.

7. The method of claim 1, wherein the solid phase comprises a continuous or non-continuous coating over the target surface.

8. The method of claim 7, comprising depositing an inorganic coating on top of the coating formed by the solid phase.

9. The method of claim 1, comprising depositing a graded-composition barrier coating on a coating formed by the solid phase, wherein the graded-composition barrier coating comprises an inorganic and an organic material including a composition which varies substantially continuously across a thickness of the graded-composition barrier coating.

10. The method of claim 1, comprising heating non-target surfaces within the deposition chamber to a temperature sufficient to substantially limit condensation on the non-target surfaces.

11. The method of claim 1, comprising forming menisci in the liquid phase of the material to the adjacent surface features of the target surface and/or particles on the target surface.

12. The method of claim 1, comprising forming a smoothing and/or planarizing coating over structures or particles on the target surface, wherein a thickness of the coating is on the same order of magnitude or greater than a thickness of the structures or particles.

13. The method of claim 1, wherein solidifying the liquid phase of the material into the solid phase comprises forming a smoothing coating, and comprising forming a barrier coating over the smoothing coating.

14. The method of claim 1, wherein the material comprises radiation-curable alkenes and/or alkynes.

15. The method of claim 1, wherein the target surface comprises features of a glass, metal foil or plastic substrate, a plastic substrate with barrier, an optoelectronic device, an organic light emitting diode, a liquid crystal display, a photovoltaic device, an integrated circuit, a sensor, an electrochromic device, or a medical diagnostic device.

16. A system, comprising:
a deposition chamber;
an inlet system capable of supplying organic material as a vapor and an inert gas in the deposition chamber;
a condensation control system capable of controlling condensation of the organic material into a liquid phase on a target surface within the deposition chamber; and
a solidification feature capable of initiating curing and/or cross-linking of the liquid phase of the organic material into a solid phase within the deposition chamber.

17. The system of claim 16, wherein the deposition chamber comprises a hot-wall deposition chamber.

18. The system of claim 16, wherein the solidification feature comprises an ultra-violet light or an ultraviolet and visible light source.

19. The system of claim 16, wherein the inlet system is capable of delivering the organic material onto the target surface directly or indirectly regardless of line of sight.

20. The system of claim 16, wherein the inlet system comprises a showerhead, an injector, a mass flow controller, and/or a bubbler.

21. The system of claim 16, comprising a trap disposed along the inlet system before the hot-wall deposition chamber, wherein the trap is capable of being kept at a lower temperature than temperatures of non-target surfaces within the hot-wall deposition chamber.

22. A method comprising:
flowing a precursor vapor into a deposition chamber via a heated inlet system, wherein the precursor vapor comprises a material in a gas phase and an inert gas;
condensing the material into a stable liquid phase on a target surface of a component positioned on an electrode within the deposition chamber; and
solidifying the stable liquid phase of the material disposed on the target surface into a solid layer within the deposition chamber.

23. The method of claim 22, comprising solidifying the stable liquid phase of the material by activating an ultra-violet light disposed within the deposition chamber.

24. The method of claim 22, comprising solidifying the stable liquid phase of the material via exposure to a plasma within the deposition chamber, wherein the plasma is formed by ignition of the inert gas.

25. The method of claim 22, wherein the component comprises a glass, metal foil or plastic substrate, a plastic substrate with barrier, an optoelectronic device, an organic light emitting diode, a liquid crystal display, a photovoltaic device, an integrated circuit, a sensor, an electrochromic device, or a medical diagnostic device.

26. A method comprising:
forming a smoothing layer on a target, comprising:
condensing a material into a liquid phase on the target within the deposition chamber; and
solidifying the liquid phase of the material disposed on the target within the deposition chamber to form the smoothing layer; and
forming a barrier coating on the target within the deposition chamber.

27. The method of claim 26, comprising flowing a precursor vapor into the deposition chamber via a heated inlet system, wherein the precursor vapor comprises the material in a gas phase.

28. The method of claim 26, comprising forming the barrier coating on the smoothing layer.

29. The method of claim 26, comprising forming the smoothing layer on the barrier coating.

30. The method of claim 26, comprising:
forming the barrier coating over the smoothing layer; and
forming a second smoothing layer on the barrier coating, comprising:
condensing a second material into a liquid phase of the second material on the target within the deposition chamber; and
solidifying the liquid phase of the second material within the deposition chamber to form the second smoothing layer, wherein the second smoothing layer is configured for impact and/or abrasion resistance.

31. The method of claim 26, wherein the material comprises an organic material.
